(19) United States
(12) Patent Application Publication
(10) Pub. No.: US 2026/0173626 A1
(43) Pub. Date: Jun. 18, 2026

(54) TRANSPARENT DISPLAY APPARATUS

(71) Applicant: SAMSUNG ELECTRONICS CO., LTD., Suwon-si (KR)

(72) Inventors: Yeseul PARK, Suwon-si (KR); Tatsuhiro SUWA, Suwon-si (KR); Takashige FUJIMORI, Suwon-si (KR); Soonmin CHA, Suwon-si (KR); Kyunghoon CHUNG, Suwon-si (KR); Hyeondong LEE, Suwon-si (KR); Younghoon SHIN, Suwon-si (KR)

(21) Appl. No.: 19/369,955

(22) Filed: Oct. 27, 2025

Related U.S. Application Data
(63) Continuation of application No. PCT/KR2025/015593, filed on Oct. 1, 2025.

(30) Foreign Application Priority Data
Dec. 16, 2024 (KR) 10-2024-0187249
Jan. 6, 2025 (KR) 10-2025-0001783

(51) Int. Cl. H10H 29/854; H01L 25/075; H10H 29/855

(52) U.S. Cl. CPC H10H 29/854; H10H 29/855; H10W 90/00

(57) ABSTRACT

A transparent display apparatus includes a plurality of transparent display modules arranged in an M×N matrix format, a filler disposed in a gap between the plurality of transparent display modules, and a light-transmitting cover configured to cover front surfaces of the plurality of transparent display modules and a front surface of the filler. The filler includes a first light-transmitting resin layer disposed in a gap between and arranged parallel to light-transmitting substrates of adjacent transparent display modules among the plurality of transparent display modules, the first light-transmitting resin layer having a refractive index matched with a refractive index of the light-transmitting substrates; and a second light-transmitting resin layer disposed in a gap between and arranged parallel to front layers of adjacent transparent display modules among the plurality of transparent display modules, the second light-transmitting resin layer having a color value matched with a color value of the front layers.

### CROSS-REFERENCE TO RELATED APPLICATIONS

This application is a continuation of International Application No. PCT/KR2025/015593 designating the United States, filed on Oct. 1, 2025, in the Korean Intellectual Property Receiving Office and claiming priority to Korean Patent Application Nos. 10-2024-0187249, filed on Dec. 16, 2024, and 10-2025-0001783, filed on Jan. 6, 2025, in the Korean Intellectual Property Office, the disclosures of each of which are incorporated by reference herein in their entireties.

### BACKGROUND

### Field

The disclosure relates to a transparent display apparatus.

### Description of Related Art

A display apparatus may be classified into a self-emitting display in which each pixel emits light by itself and a passive light-emitting display that requires a separate light source.

A liquid crystal display (LCD) is one of passive light-emitting displays, and needs a backlight unit configured to supply light from the rear of a display panel, a liquid crystal layer configured to serve as a switch to transmit/block light, a color filter configured to change supplied light to a desired color, and the like. Thus, the LCD is complex in structure and has a limitation in realizing a small thickness.

On the other hand, in the self-emitting display in which each pixel emits light by itself by including a light-emitting element for each pixel, components, such as a backlight unit and a liquid crystal layer are not required and a color filter may also be omitted. Thus, the self-emitting display is structurally simple and may have a high degree of freedom in design. In addition, the self-emitting display may realize not only a small thickness, but also an excellent contrast ratio, brightness, and viewing angle.

Among self-emitting displays, a micro-LED display includes a plurality of LEDs having a size on the order of micrometers. Compared with an LCD requiring a backlight, the micro-LED display may provide excellent contrast, superior response time, and improved energy efficiency.

In addition, when micro-LEDs are employed, areas occupied by wiring and LEDs may be minimized/reduced, making it possible to manufacture a transparent display apparatus.

There exist technical and economic limitations in manufacturing a relatively large transparent display apparatus as a single panel, and therefore a method of tiling a plurality of transparent display modules has been suggested as an alternative. In the tiling method, seams between the transparent display modules may become visually perceptible.

### SUMMARY

Embodiments of the disclosure provide a transparent display apparatus that is improved to reduce the visibility of gaps between a plurality of transparent display modules.

Embodiments of the disclosure provide a transparent display apparatus improved to prevent and/or reduce a light-transmitting resin disposed in a gap between a plurality of transparent display modules from being damaged.

Embodiments of the disclosure provide a transparent display apparatus improved to allow a transparent display module to be easily separated from a base substrate during repair or replacement of the transparent display module.

Embodiments of the disclosure provide a transparent display apparatus improved to allow a front optical layer, such as an optical film, to be easily separated from a light-transmitting cover that covers a front surface of a transparent display module.

The technical objectives of the disclosure are not limited to the above, and other objectives that are not described above will be clearly understood by those skilled in the art from the above detailed description.

A transparent display apparatus according to an example embodiment of the disclosure may include: a plurality of transparent display modules, each including a transparent display, arranged in an M×N matrix format; a filler disposed in a gap between the plurality of transparent display modules; and a light-transmitting cover configured to cover front surfaces of the plurality of transparent display modules and a front surface of the filler. Each of the plurality of transparent display modules may include: a light-transmitting substrate; and a front layer disposed in front of the light-transmitting substrate, the front layer including a plurality of light-emitting elements comprising light-emitting circuitry mounted on a front surface of the light-transmitting substrate and configured to emit light forward, and a mounting-surface cover surrounding the plurality of light-emitting elements and the front surface of the light-transmitting substrate and configured to allow light to be transmitted therethrough. The filler may include a first light-transmitting resin layer disposed in a gap between light-transmitting substrates of adjacent transparent display modules among the plurality of transparent display modules, arranged parallel to the light-transmitting substrates and having a refractive index matching a refractive index of the light-transmitting substrates; and a second light-transmitting resin layer disposed in a gap between front layers of the adjacent transparent display modules among the plurality of transparent display modules, arranged parallel to the front layers and having a color value matching a color value of the front layers.

A transparent display apparatus according to an example embodiment of the present disclosure may include: a base substrate configured to allow light to be transmitted therethrough; a plurality of transparent display modules, each including a transparent display, arranged on a front surface of the base substrate; a filler disposed in a gap between the plurality of transparent display modules; and a light-transmitting cover including a first region covering front surfaces of the plurality of transparent display modules and a second region that covers a front surface of the filler. Each of the plurality of transparent display modules may include: a light-transmitting substrate; a front layer including a circuit pattern layer provided on a front surface of the light-transmitting substrate; a plurality of light-emitting elements comprising light-emitting circuitry mounted on the front surface of the light-transmitting substrate and electrically connected to the circuit pattern layer; and a mounting-surface cover surrounding the circuit pattern layer, the plurality of light-emitting elements, and the front surface of the light-transmitting substrate, and configured to allow light to be transmitted therethrough. The filler may include: a first light-transmitting resin layer disposed parallel to the light-transmitting substrate in the gap and having a refractive index matching a refractive index of the light-transmitting substrate; and a second light-transmitting resin layer disposed parallel to the front layer in the gap and having a color value matching a color value of the front layer. The light transmittance of light sequentially passing through the light-transmitting substrate, the front layer, and the first region, and the light transmittance of light sequentially passing through the first light-transmitting resin layer, the second light-transmitting resin layer, and the second region may match each other.

A transparent display apparatus according to an example embodiment of the present disclosure may include: a base substrate configured to allow light to be transmitted therethrough; a plurality of transparent display modules, each comprising a transparent display, mounted on a front surface of the base substrate; and a light-transmitting resin configured to allow light to be transmitted therethrough. Each of the plurality of transparent display modules may include: a light-transmitting substrate; and a front layer disposed on a front surface of the light-transmitting substrate, the front layer including a circuit pattern layer provided on the front surface of the light-transmitting substrate, a plurality of light-emitting elements comprising light-emitting circuitry mounted on the front surface of the light-transmitting substrate and electrically connected to the circuit pattern layer, and a mounting-surface cover surrounding the circuit pattern layer, the plurality of light-emitting elements, and the front surface of the light-transmitting substrate, and configured to transmit light therethrough. A first portion of the light-transmitting resin may fill a gap between the plurality of transparent display modules. A second portion of the light-transmitting resin may cover front surfaces of the plurality of transparent display modules. A refractive index of the light-transmitting resin may match a refractive index of the light-transmitting substrate. A color value of the light-transmitting resin may match a color value of the front layer. The light transmittance of light sequentially passing through the base substrate, the light-transmitting substrate, the front layer, and the second portion of the light-transmitting resin, and the light transmittance of light sequentially passing through the base substrate and the first portion of the light-transmitting resin match each other.

### BRIEF DESCRIPTION OF THE DRAWINGS

The above and other aspects, features and advantages of certain embodiments of the present disclosure will be more apparent from the following detailed description, taken in conjunction with the accompanying drawings, in which:

FIG. 1 is a perspective view illustrating a transparent display apparatus according to various embodiments;

FIG. 2 is a diagram illustrating an installation example of the transparent display apparatus according to various embodiments;

FIG. 3 is an enlarged cross-sectional view illustrating a part of a transparent display module of the transparent display apparatus according to various embodiments;

FIG. 4 is a diagram illustrating a state in which a plurality of transparent display modules of the transparent display apparatus are tiled, and illustrating gaps between the plurality of transparent display modules according to various embodiments;

FIG. 5 is an enlarged cross-sectional view illustrating a plurality of transparent display modules disposed on a base substrate of the transparent display apparatus and gaps therebetween according to various embodiments;

FIG. 6 is an enlarged cross-sectional view illustrating a part of the transparent display apparatus according to various embodiments;

FIG. 7 is an enlarged cross-sectional view illustrating various components of the transparent display, including a base substrate, a plurality of transparent display modules disposed on the base substrate, a filler disposed in a gap between the plurality of transparent display modules, a light-transmitting cover covering front surfaces of the plurality of transparent display modules and the filler, and a rear adhesive layer for bonding the plurality of transparent display modules to the base substrate according to various embodiments;

FIG. 8 is an enlarged cross-sectional view illustrating various components of the transparent display apparatus, including a plurality of transparent display modules, a filler disposed in a gap between the plurality of transparent display modules, a light-transmitting cover covering front surfaces of the plurality of transparent display modules and the filler, a front optical layer disposed on a front surface of the light-transmitting cover, a protective film, and a front adhesive layer for bonding the front optical layer to the plurality of transparent display modules according to various embodiments;.

FIG. 9 is an enlarged cross-sectional view illustrating a part of a transparent display apparatus according to various embodiments;

FIG. 10 is an enlarged cross-sectional view illustrating a part of a transparent display apparatus according to various embodiments;

FIG. 11 is a graph illustrating a yellowness index according to the total light transmittance in a transparent display apparatus according to various embodiments and a comparative example; and

FIG. 12 is a graph illustrating a chroma difference between an area of a transparent display module and a gap area according to the amount of dye added to a light-transmitting resin in a transparent display apparatus according to various embodiments and a comparative example.

### DETAILED DESCRIPTION

Various example embodiments described in the disclosure and the configurations shown in the drawings are simply examples, and various modifications may be made at the time of filing of the disclosure to replace or modify various embodiments and drawings of the disclosure.

In the description of the drawings, like numbers refer to like elements throughout the description of the drawings.

The terms used herein are for the purpose of describing various embodiments and are not intended to restrict and/or to limit the disclosure. The singular expressions herein may include plural expressions, unless the context clearly dictates otherwise. In addition, the terms “comprises”, “includes”, and “has” are intended to indicate that there are features, numbers, steps, operations, elements, parts, or combinations thereof described in the disclosure, and do not exclude the presence or addition of one or more other features, numbers, steps, operations, elements, parts, or combinations thereof.

It will be understood that, although the terms first, second, etc. used in the disclosure may be used herein to describe various components, these components should not be limited by these terms. These terms are simply used to distinguish one component from another. For example, a first element could be termed a second element, and similarly, a second element could be termed a first element without departing from the scope of the disclosure. The term “and/or” includes combinations of one or all of a plurality of associated listed items.

Terms such as parts, modules, members, and blocks may be implemented using software or hardware, and a plurality of parts, modules, members, and blocks are implemented as a single element, or one part, module, member, or block may also include a plurality of elements.

Hereinafter, various example embodiments of the present disclosure will be described in greater detail with reference to the accompanying drawings.

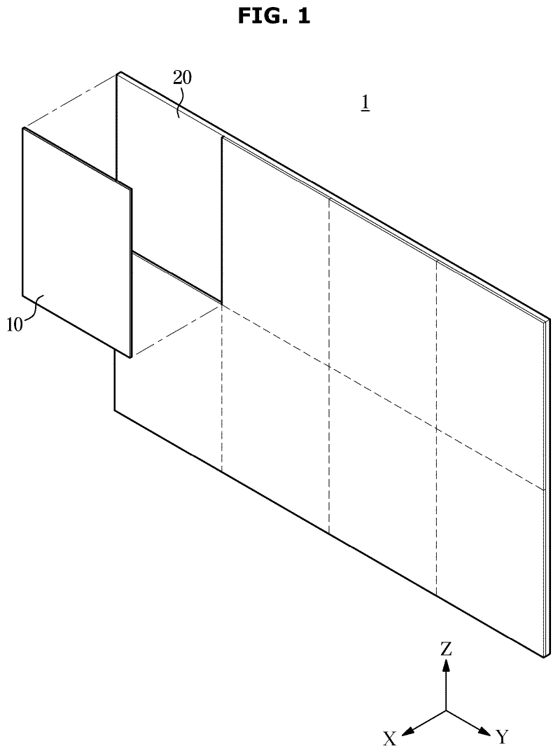

In describing various embodiments of the present disclosure with reference to FIGS. 1 to 12, terms, such as ‘front-rear direction,’ ‘vertical direction,’ and ‘horizontal direction (left-right direction)’ used in the following description are defined based on the drawings, and the shapes and positions of the respective components are not limited by these terms. For example, the term ‘front-rear direction’ may refer to a direction parallel to the X-axis based on the drawings. For example, the term ‘vertical direction’ may refer to a direction parallel to the Z-axis based on the drawings. For example, the term ‘horizontal direction (left-right direction)’ may refer to directions parallel to the Y-axis based on the drawings.

The coordinate system of the XYZ axes illustrated in FIGS. 1 to 10 is based on a transparent display apparatus 1 according to various embodiments, in which a plane on which a screen of the transparent display apparatus 1 is disposed may be defined as a Y-Z plane, and a direction in which an image is output from the transparent display apparatus 1 or light is emitted from a light-emitting element may be defined as an X direction.

In the following example embodiments, a direction in which an image is output from the transparent display apparatus 1 or light is emitted from a light-emitting element may be defined as a ‘front,’ and a direction opposite thereto may be defined as a ‘rear.’

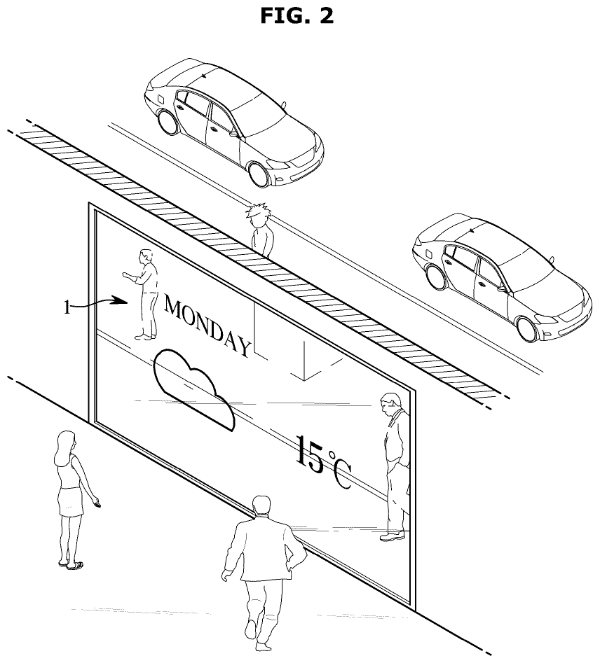

FIG. 1 is a perspective view illustrating an example transparent display apparatus according to various embodiments. FIG. 2 is a diagram illustrating an installation example of the transparent display apparatus according to various embodiments.

Referring to FIGS. 1 and 2, a transparent display apparatus 1 according to various embodiments of the present disclosure is an apparatus that may process an image signal received from an outside and visually display the processed image.

For example, the transparent display apparatus 1 according to various embodiments of the present disclosure may be implemented in various forms, such as a television (TV), a monitor, which is a type of output device of a computer, a portable multimedia device, and a portable communication device. For example, the transparent display apparatus 1 according to various embodiments of the present disclosure may be a large format display (LFD) installed outdoors, such as a rooftop or a bus stop. The term “outdoors” is not limited to the open air, but the transparent display apparatus 1 according to various embodiments of the present disclosure may be installed in places that, although indoors, may be accessed by a large number of people, such as subway stations, shopping malls, movie theaters, companies, and stores. The type of transparent display apparatus 1 according to various embodiments of the present disclosure is not limited to the examples described above, as long as it is an apparatus that can visually display images.

For example, the transparent display apparatus 1 may be installed in a standing manner on the floor or furniture indoors or outdoors. For example, the transparent display apparatus 1 may be installed on or inside a wall of a building or other structure. For example, the transparent display apparatus 1 may be installed on a wall by a wall mount device.

In FIG. 1, a flat-panel display apparatus with a flat screen is illustrated as an example of the transparent display apparatus 1, but the disclosure is not limited thereto, and the transparent display apparatus 1 according to various embodiments of the present disclosure may include a curved display apparatus or a bendable or flexible display apparatus in which a flat state and a curved state are variable. The configuration of the present disclosure described below may be applied to transparent display apparatuses of various shapes, regardless of the screen size or aspect ratio.

The transparent display apparatus 1 may receive content including video signals and audio signals from various content sources and may output video and audio corresponding to the video signals and the audio signals. For example, the transparent display apparatus 1 may receive content data through a broadcast reception antenna or a wired cable, receive content data from a content playback device, or receive content data from a content providing server of a content provider.

The transparent display apparatus 1 may display an image corresponding to video data and output sound corresponding to audio data. For example, the transparent display apparatus 1 may restore a plurality of image frames included in the video data and sequentially display the plurality of image frames. In addition, the transparent display apparatus 1 may restore audio signals included in the audio data and sequentially output sound according to the audio signals.

The transparent display apparatus 1 may include a screen configured to display images. The screen may be provided on one side of the transparent display apparatus 1. The side on which the screen is provided may be defined as a front side of the transparent display apparatus 1. The screen may be provided on the front surface of the transparent display apparatus 1. The screen may be configured to display images forward. For example, the screen may display a still image or a moving image. For example, the screen may display a two-dimensional plane image or a three-dimensional stereoscopic image.

A plurality of pixels may be formed on the screen. The image displayed on the screen may be formed by light emitted by each of the plurality of pixels. For example, the light emitted from the plurality of pixels may be combined like a mosaic, thereby forming an image on the screen.

Each of the plurality of pixels may emit different brightness and different color of light. Particularly, each of the plurality of pixels P may include sub-pixels, and the sub-pixels may include a red sub pixel emitting red light, a green sub pixel emitting green light, and a blue sub pixel emitting blue light. For example, the red light may represent a light beam having a wavelength of approximately 620 nm (nanometers, one billionth of a meter) to 750 nm, the green light may represent a light beam having a wavelength of approximately 495 nm to 570 nm, and the blue light may represent a light beam having a wavelength of approximately 450 nm to 495 nm.

By a combination of the light emitted from the red sub pixel, the green sub pixel, and the blue sub pixel, each of the plurality of pixels may emit different brightness and different color of light.

The sub-pixels may be arranged along a horizontal direction (Y direction). The sub-pixels may be arranged along a vertical direction (Z direction). Alternatively, the sub-pixels may not be arranged in a line with each other.

The transparent display apparatus 1 according to an embodiment may be a self-emitting display apparatus in which a light-emitting element is disposed in each pixel, allowing each pixel to emit light by itself. In such an embodiment, unlike a liquid crystal display apparatus, the transparent display apparatus 1, does not require components, such as a backlight unit or a liquid crystal layer, and thus may implement a small thickness, and may have a relatively simple structure, which enables various design modifications.

The transparent display apparatus 1 according to an embodiment may employ an inorganic light-emitting element, such as an inorganic LED, as a light-emitting element disposed in each pixel. The inorganic light-emitting element has a faster response speed compared to an organic light-emitting element such as an organic light emitting diode (OLED), and may achieve high luminance with low power consumption.

In comparison with the organic light-emitting element that requires an encapsulation process because the organic light-emitting element is vulnerable to exposure to moisture and oxygen and has poor durability, the inorganic light-emitting element that may be included in a transparent display apparatus 1 according to an embodiment may have high durability without requiring a separate encapsulation process.

The inorganic light-emitting element employed in the transparent display apparatus 1 according to an embodiment may be a micro-LED having a short side length of about 100 μm, on the order of several tens of micrometers, or on the order of several micrometers. As described above, by employing micro-sized LEDs, a pixel size may be reduced and a higher resolution may be realized even within the same size screen.

When the LED chip is fabricated to a micro-sized scale, breakage upon bending, which occurs due to the properties of inorganic materials, may be avoided. That is, when a micro-LED chip is transferred onto a flexible substrate, the LED chip does not break even when the substrate is bent, and thus a flexible display apparatus may also be realized.

A display apparatus employing a micro-LED may be applied to various fields using an ultra-small pixel size and a thin thickness. As an example, as shown in FIG. 1, by tiling a plurality of display modules 10, onto a plurality of micro-LEDs are transferred, on a base substrate 20, a large-area screen may be realized, and a display apparatus of such a large-size screen may be used as a signage, an electric billboard, or the like.

A display apparatus in which a plurality of micro LEDs are transferred, such as the transparent display apparatus 1 according to an embodiment, may be implemented in a flexible form, and by utilizing such characteristics, may also be implemented as a foldable display apparatus or a rollable display apparatus.

A transparent display apparatus 1 according to an embodiment of the present disclosure may be configured to allow light to be transmitted therethrough. For example, the transparent display apparatus 1 may be configured to allow light to be transmitted in the front-rear direction X. For example, the transparent display apparatus 1 may be configured such that light may be transmitted from the front to the rear, or from the rear to the front. As shown in FIG. 2, a viewer may see not only an image displayed on the screen of the transparent display apparatus 1 but also objects beyond the image through the transparent display apparatus 1.

The transparent display apparatus 1 may include a plurality of transparent display modules 10 and a base substrate 20.

Each of the plurality of transparent display modules 10 may be provided to output an image. The transparent display apparatus 1 may provide a single large image by combining images of the plurality of transparent display modules 10.

Each of the plurality of transparent display modules 10 may be configured to allow light to be transmitted therethrough. Each of the plurality of transparent display modules 10 may be configured to allow light to be transmitted in the front-rear direction X.

The plurality of transparent display modules 10 may be arranged on the base substrate 20. The plurality of transparent display modules 10 may be arranged on one surface (e.g., the front surface) of the base substrate 20. The plurality of transparent display modules 10 may be mounted on the base substrate 20. The plurality of transparent display modules 10 may be supported by the base substrate 20. The plurality of transparent display modules 10 may be tiled on the base substrate 20. The plurality of transparent display modules 10 may be arranged in an M×N matrix form on the base substrate 20 (where M and N are natural numbers, and at least one of M and N is a natural number greater than one (1)).

The base substrate 20 may be provided to allow light to be transmitted therethrough. The base substrate 20 may be provided to allow light to be transmitted in the front-rear direction X. For example, the base substrate 20 may include a material, such as glass or light-transmitting resin.

As described above, the transparent display apparatus 1 according to an embodiment includes the transparent display modules 10 and the base substrate 20, each of which is light-transmitting, and thus may be provided to allow light to be transmitted therethrough as a whole.

As described above, the transparent display apparatus 1 according to an embodiment may be a self-emitting display apparatus that uses an inorganic light-emitting element as a light source. Therefore, the transparent display apparatus 1 does not need to have a backlight unit, a liquid crystal layer, or an encapsulation layer, and may be implemented with very small micro LEDs and a driving circuit for driving micro LEDs and wirings, which is more beneficial in ensuring the aperture ratio, one of the important factors in the implementation of the transparent display apparatus 1.

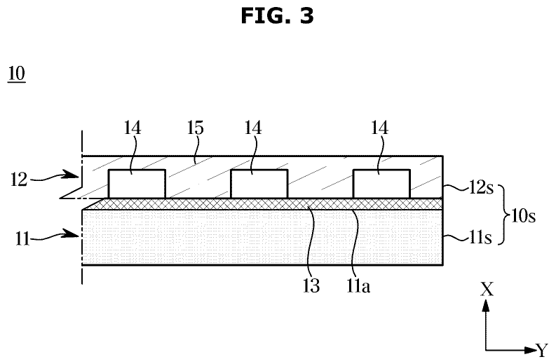

FIG. 3 is an enlarged cross-sectional view illustrating a part of a transparent display module of the transparent display apparatus according to various embodiments.

Referring to FIG. 3, the structure of one of the plurality of transparent display modules 10 included in the transparent display apparatus 1 according to an embodiment of the present disclosure will be described in greater detail, and the structure of the transparent display module 10 described below may be applied correspondingly to each of the plurality of transparent display modules 10.

The transparent display module 10 may include a light-transmitting substrate 11. The light-transmitting substrate 11 may be provided to support other components of the transparent display module 10.

The light-transmitting substrate 11 may be provided to allow light to be transmitted therethrough. For example, the light-transmitting substrate 11 may be provided to allow light to be transmitted in the front-rear direction X. The light-transmitting substrate 11 may include materials, such as transparent glass or resin.

The transparent display module 10 may include a circuit pattern layer 13 provided on one surface of the light-transmitting substrate 11. The circuit pattern layer 13 may be provided on a mounting-surface 11a of the light-transmitting substrate 11. The circuit pattern layer 13 may be provided on a front surface of the light-transmitting substrate 11. The circuit pattern layer 13 may be electrically connected to a light-emitting element 14, to be described below, which is mounted on the mounting-surface 11a of the light-transmitting substrate 11. The circuit pattern layer 13 may deliver an electrical signal from a driving board of the transparent display apparatus 1 to the light-emitting element 14. The circuit pattern layer 13 may apply a driving voltage/current to the light-emitting element 14.

For example, the circuit pattern layer 13 may include a thin film transistor (TFT) layer and various wirings (e.g., data lines, gate lines, power lines, and the like).

The thin film transistor layer may include a transistor circuit for individually controlling the light-emitting elements 14 to be described below.

The various wirings may deliver various electrical signals (e.g., data signals, gate signals, power signals to the light-emitting elements 14.

The transparent display module 10 may include a plurality of light-emitting elements 14 provided to emit light. The plurality of light-emitting elements 14 may be provided to emit light substantially forward. The plurality of light-emitting elements 14 may include the pixels provided on the screen of the transparent display apparatus 1.

The plurality of light-emitting elements 14 may be mounted on the light-transmitting substrate 11. The plurality of light-emitting elements 14 may be mounted on the mounting-surface 11a of the light-transmitting substrate 11. The plurality of light-emitting elements 14 may be mounted on the front surface of the light-transmitting substrate 11. The plurality of light-emitting elements 14 may be disposed on the circuit pattern layer 13 provided on the mounting-surface 11a of the light-transmitting substrate 11.

The transparent display module 10 may include a mounting-surface cover 15. The mounting-surface cover 15 may surround the plurality of light-emitting elements 14. The mounting-surface cover 15 may surround the circuit pattern layer 13. The mounting-surface cover 15 may cover the front surface of the light-transmitting substrate 11. The mounting-surface cover 15 may cover the mounting-surface 11a of the light-transmitting substrate 11.

The mounting-surface cover 15 may protect various components provided on the mounting-surface 11a of the light-transmitting substrate 11, such as the plurality of light-emitting elements 14 and the circuit pattern layer 13, by covering the components. As an example, the mounting-surface cover 15 may have a substantially flat front surface, so that the overall front surface of the transparent display module 10 may be flat.

The mounting-surface cover 15 may be provided to allow light to be transmitted therethrough. The mounting-surface cover 15 may be provided to allow light to be transmitted in the front-rear direction.

For example, the mounting-surface cover 15 may include a material, such as a light-transmitting resin. For example, the mounting-surface cover 15 may be formed through operations of applying a light-transmitting resin to a side of the mounting-surface 11a of the light-transmitting substrate 11 on which the circuit pattern layer 13 and the plurality of light-emitting elements 14 are provided, planarizing the front surface, and then curing the resin.

The transparent display apparatus 1 may include a front layer 12 disposed in front of the light-transmitting substrate 11. The front layer 12 may be disposed on the front surface of the light-transmitting substrate 11. The front layer 12 may include the circuit pattern layer 13. The front layer 12 may include the light-emitting element 14. The front layer 12 may include the mounting-surface cover 15. That is, the circuit pattern layer 13, the light-emitting element 14, and the mounting-surface cover 15 described above may include the front layer 12 in front of the light-transmitting substrate 11.

With such a configuration, the transparent display module 10 may output an image forward and may be configured to allow light to be transmitted in the front-rear direction X.

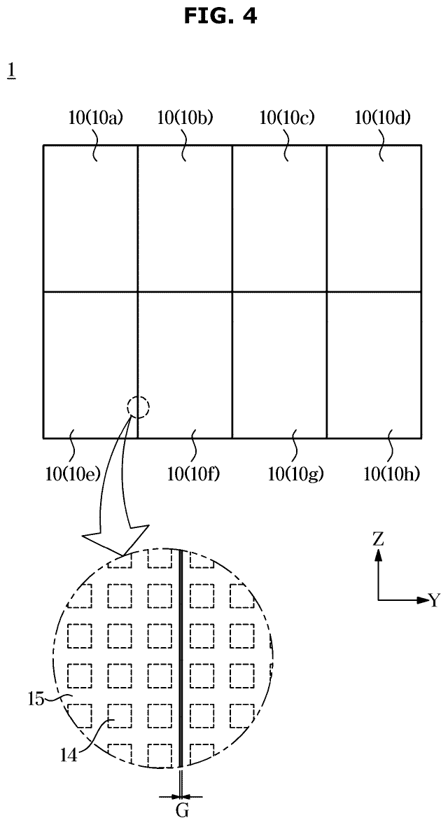

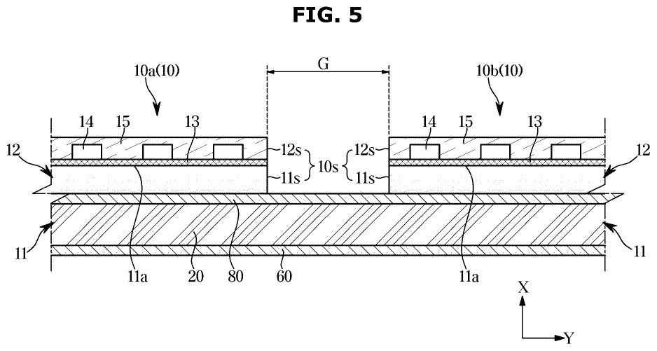

FIG. 4 is a diagram illustrating a state in which a plurality of transparent display modules of the transparent display apparatus are tiled, and illustrating gaps between the plurality of transparent display modules according to various embodiments. FIG. 5 is an enlarged cross-sectional view illustrating a plurality of transparent display modules disposed on a base substrate of the transparent display apparatus and gaps therebetween according to various embodiments.

Referring to FIGS. 4 and 5, the plurality of transparent display modules 10 of the transparent display apparatus 1 according to an embodiment of the present disclosure may be tiled on the base substrate 20. For example, the plurality of transparent display modules 10 may be arranged in a matrix form. In FIG. 4, a plurality of transparent display modules 10 are illustrates as being arranged in a matrix with 2 rows and 4 columns, but the arrangement of the transparent display modules 10 is not limited thereto in various embodiments.

The plurality of transparent display modules 10 may be arranged adjacent to each other. However, a gap G may be formed between a pair of adjacent transparent display modules 10 among the plurality of transparent display modules 10. In FIGS. 4 and 5, a gap G formed between a pair of transparent display modules 10 adjacent to each other in the horizontal direction Y is illustrated in greater detail, but a gap G may also be formed between a pair of transparent display modules 10 adjacent to each other in the vertical direction Z. For example, a gap G may be formed between a first display module 10a and a second display module 10b, between the second display module 10b and a third display module 10c, between the third display module 10c and a fourth display module 10d, between a fifth display module 10e and a sixth display module 10f, between the sixth display module 10f and a seventh display module 10g, and between the seventh display module 10g and an eighth display module 10h, all of which are adjacent in the horizontal direction Y, but also a gap G may also be formed between the first display module 10a and the fifth display module 10e, between the second display module 10b and the sixth display module 10f, between the third display module 10c and the seventh display module 10g, and between the fourth display module 10d and the eighth display module 10h, all of which are adjacent in the vertical direction Z.

As shown in FIG. 5, the gap G may be formed between adjacent side surfaces 10s of a pair of adjacent transparent display modules 10.

The gap G formed between the plurality of transparent display modules 10 may have a light transmittance, a refractive index, a color, a brightness, a chroma, and the like that differ from each of the transparent display modules 10, which may allow the gap G to be easily perceived. When the gap G is perceived through the screen of the transparent display apparatus 1, it may cause visual discomfort to the viewer, and thus it is important to reduce the visibility of the gap G.

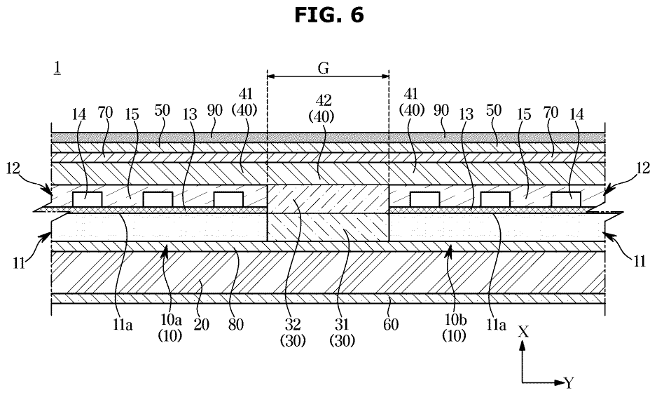

FIG. 6 is an enlarged cross-sectional view illustrating a part of the transparent display apparatus according to various embodiments.

Referring to FIG. 6, the transparent display apparatus 1 according to an embodiment of the present disclosure may include a filler 30 disposed in the gap G between the plurality of transparent display modules 10. The filler 30 may fill the gap G. The filler 30 may be disposed between side surfaces 10s of a pair of adjacent transparent display apparatuses 1 among a plurality of transparent display apparatuses 1. For example, the filler 30 may be coupled to a side surface 10s of one transparent display module 10 and a side surface 10s of another transparent display module 10 adjacent to the transparent display module 10. For the filler 30 may be attached to a side surface 10s of one transparent display module 10 and a side surface 10s of another transparent display module 10 adjacent to the transparent display module 10.

The filler 30 may be provided to allow light to be transmitted therethrough. The filler 30 may be provided to allow light to be transmitted in the front-rear direction X. Light may sequentially pass through the base substrate 20 and the filler 30 and proceed from the rear toward the front of the transparent display apparatus 1, or may sequentially pass through the filler 30 and the base substrate 20 and proceed from the front toward the rear of the transparent display apparatus 1.

For example, the filler 30 may include a light-transmitting resin. For example, the filler 30 may be formed by injecting a light-transmitting resin into the gap G and then curing the resin (e.g., curing using heat or ultraviolet light).

The transparent display apparatus 1 may include a light-transmitting cover 40. The light-transmitting cover 40 may cover the front surfaces of the plurality of transparent display modules 10. The light-transmitting cover 40 may cover the front surface of the filler 30. The light-transmitting cover 40 may include a first region 41 covering the front surfaces of the plurality of transparent display modules 10 and a second region 42 covering the front surface of the filler 30.

The light-transmitting cover 40 may be provided to allow light to be transmitted therethrough. The light-transmitting cover 40 may be provided to allow light to be transmitted in the front-rear direction X. Light may sequentially pass through the base substrate 20, the transparent display module 10, and the first region 41 of the light-transmitting cover 40 and proceed from the rear toward the front of the transparent display apparatus 1, and may sequentially pass through the first region 41 of the light-transmitting cover 40, the transparent display module 10, and the base substrate 20 and proceed from the front toward the rear of the transparent display apparatus 1. Light may sequentially pass through the base substrate 20, the filler 30, and the second region 42 of the light-transmitting cover 40 and proceed from the rear toward the front of the transparent display apparatus 1, and may sequentially pass through the second region 42 of the light-transmitting cover 40, the filler 30, and the base substrate 20 and proceed from the front toward the rear of the transparent display apparatus 1.

For example, the light-transmitting cover 40 may include a light-transmitting resin. For example, the light-transmitting cover 40 may be formed by applying a light-transmitting resin to the front surfaces of the plurality of transparent display modules 10 and the filler 30 and then curing the resin (e.g., curing using heat or ultraviolet light).

According to an embodiment, the filler 30 and the light-transmitting cover 40 may each include a light-transmitting resin. For example, the filler 30 and the light-transmitting cover 40 may include a curable resin, such as epoxy. The filler 30 and the light-transmitting cover 40 may each or collectively be referred to as a “light-transmitting resin”.

In order to more effectively prevent and/or reduce the gap G between the plurality of transparent display modules 10 or the filler 30 filled therein from being visually perceived, characteristics of the filler 30 and the light-transmitting cover 40, such as a light transmittance, a refractive index, and a color value may be determined as follows.

According to an embodiment, at least a portion of the filler 30 may have a refractive index that is matched with a refractive index of the light-transmitting substrate 11. For example, the filler 30 may include a first light-transmitting resin layer 31 having a refractive index that is matched with a refractive index of the light-transmitting substrate 11.

It will be understood that when refractive indices are being “matched”, the refractive indices are the same or very similar as each other such that the plurality of transparent display modules 10 and the filler 30 disposed in the gap therebetween are barely distinguishable. The refractive index of the first light-transmitting resin layer 31 and the refractive index of the light-transmitting substrate 11 may be the same or very similar so as to be nearly the same. The difference in refractive index between the first light-transmitting resin layer 31 and the light-transmitting substrate 11 may be less than or equal to a certain value.

According to an embodiment, the refractive index of the first light-transmitting resin layer 31 and the refractive index of the light-transmitting substrate 11, which are matched with each other, may be determined as the refractive index for a specific wavelength. For example, the refractive index of the first light-transmitting resin layer 31 in the visible light region and the refractive index of the light-transmitting substrate 11 in the visible light region may be matched with each other.

For example, the difference in refractive index between the first light-transmitting resin layer 31 and the light-transmitting substrate 11 may be approximately 0.03 or less.

For example, the refractive index of the first light-transmitting resin layer 31 may be approximately 1.50 to 1.52.

The first light-transmitting resin layer 31 may be disposed between light-transmitting substrates 11 of adjacent transparent display modules 10. The first light-transmitting resin layer 31 may be disposed in a gap formed between light-transmitting substrates 11 of adjacent transparent display modules 10. The first light-transmitting resin layer 31 may be disposed between side surfaces 11s of light-transmitting substrates 11 of adjacent transparent display modules 10. For example, the first light-transmitting resin layer 31 may be in contact with side surfaces 11s of light-transmitting substrates 11 of adjacent transparent display modules 10. For example, the first light-transmitting resin layer 31 may be attached to side surfaces 11s of light-transmitting substrates 11 of adjacent transparent display modules 10.

The first light-transmitting resin layer 31 may be disposed parallel to the light-transmitting substrates 11 in the gap between the light-transmitting substrates 11 of the adjacent transparent display modules 10. For example, the rear surface of the first light-transmitting resin layer 31 may be substantially parallel to the rear surface of the light-transmitting substrate 11. For example, the front surface of the first light-transmitting resin layer 31 may be substantially parallel to the front surface (e.g., the mounting-surface 11a) of the light-Transmitting substrate 11.

According to an embodiment, at least a portion of the filler 30 may have a color value that is matched with a color value of the front layer 12. For example, the filler 30 may include a second light-transmitting resin layer 32 having a color value that is matched with a color value of the front layer 12. The “color value” is a numerical value of the color of an object quantified according to a specific standard, hue, brightness, and chroma. For example, “color value” may be a numerical value for a color defined by coordinates, such as the CIELAB color space.

The color value of the front layer 12 may be determined according to a predetermined criterion because the arrangement of the light-emitting elements 14, the circuit pattern layer 13, etc., and the thickness of the mounting-surface cover 15 may vary depending on the position of the front layer 12 within the transparent display module 10. For example, the color value of the front layer 12 may be defined as an average color value over the entire area of the front layer 12 included in one transparent display module 10. For example, the color value of the front layer 12 may be defined as a color value in an area close to the gap G, that is, an area close to the side surface 12s of the front layer 12.

It will be understood that when color values are referred to as being “matched”, the color values are the same or very similar as each other such that the plurality of transparent display modules 10 and the filler 30 disposed in the gap therebetween are barely distinguishable. The color value of the second light-transmitting resin layer 32 and the color value of the front layer 12 may be the same or very similar so as to be nearly the same. The difference in color value between the second light-transmitting resin layer 32 and the front layer 12 may be less than or equal to a certain value.

According to an embodiment, the color value of the second light-transmitting resin layer 32 and the color value of the front layer 12 which are matched with each other may be defined by a color value according to the yellow index.

For example, the difference in the color value based on the yellowness index between the second light-transmitting resin layer 32 and the front layer 12 may be approximately 5 or less.

The second light-transmitting resin layer 32 may be disposed between front layers 12 of adjacent transparent display modules 10. The second light-transmitting resin layer 32 may be disposed in a gap formed between front layers 12 of adjacent transparent display modules 10. The second light-transmitting resin layer 32 may be disposed between side surfaces 12s of front layers 12 of adjacent transparent display modules 10. For example, the second light-transmitting resin layer 32 may be in contact with side surfaces 12s of front layers 12 of adjacent transparent display modules 10. For example, the second light-transmitting resin layer 32 may be attached to side surfaces 12s of front layers 12 of adjacent transparent display modules 10.

The second light-transmitting resin layer 32 may be disposed parallel to the front layers 12 in the gap between the front layers 12 of the adjacent transparent display modules 10. For example, the rear surface of the second light-transmitting resin layer 32 may be substantially parallel to the rear surface of the front layer 12. For example, the front surface of the second light-transmitting resin layer 32 may be substantially parallel to the front surface of the front layer.

According to an embodiment, in the transparent display apparatus 1, the light transmittance of an area corresponding to the transparent display module 10 and the light transmittance of an area corresponding to the gap G may be matched with each other. For example, the light transmittance of light passing sequentially through the light-transmitting substrate 11, the front layer 12, and the first region 41 of the light-transmitting cover 40 may be matched with the light transmittance of light passing sequentially through the first light-transmitting resin layer 31, the second light-transmitting resin layer 32, and the second region 42 of the light-transmitting cover 40.

It will be understood that when light transmittances are referred to as being “matched”, the light transmittances are the same or very similar as each other such that the plurality of transparent display modules 10 and the filler 30 disposed in the gap therebetween are barely distinguishable. The light transmittance of light passing sequentially through the light-transmitting substrate 11, the front layer 12, and the first region 41 of the light-transmitting cover 40, and the light transmittance of light passing sequentially through the first light-transmitting resin layer 31, the second light-transmitting resin layer 32, and the second region 42 of the light-transmitting cover 40 may be the same or very similar so as to be nearly the same. The difference in light transmittance of light passing sequentially through the light-transmitting substrate 11, the front layer 12, and the first region 41 of the light-transmitting cover 40, and light passing sequentially through the first light-transmitting resin layer 31, the second light-transmitting resin layer 32, and the second region 42 of the light-transmitting cover 40 may be less than or equal to a certain value.

For example, the light transmittance of light passing sequentially through the light-transmitting substrate 11, the front layer 12, and the first region 41 of the light-transmitting cover 40 may be defined as an average light transmittance over the entire area of one transparent display module 10 of the first region 41 of the light-transmitting cover 40. For example, the light transmittance of light passing sequentially through the light-transmitting substrate 11, the front layer 12, and the first region 41 of the light-transmitting cover 40 may be defined as the light transmittance in an area adjacent to the gap G.

According to an embodiment, the light transmittance of light passing sequentially through the light-transmitting substrate 11, the front layer 12, and the first region 41 of the light-transmitting cover 40, and the light transmittance of light passing sequentially through the first light-transmitting resin layer 31, the second light-transmitting resin layer 32, and the second region 42 of the light-transmitting cover 40 which are matched with each other may be determined by the light transmittance for a specific wavelength. For example, the light transmittance in the visible light region may be matched

For example, the difference in light transmittance between light passing sequentially through the light-transmitting substrate 11, the front layer 12, and the first region 41 of the light-transmitting cover 40, and light passing sequentially through the first light-transmitting resin layer 31, the second light-transmitting resin layer 32, and the second region 42 of the light-transmitting cover 40 may be approximately 0.05 or less.

For example, the refractive index of the first light-transmitting resin layer 31 may be approximately 1.50 to 1.52.

Through the above-described matching of optical characteristics, the visibility of the gap G between the plurality of transparent display modules 10 may be effectively prevented/reduced.

In addition to the matching described above, the color value of the first light-transmitting resin layer 31 and the color value of the light-transmitting substrate 11 may also be matched with each other. The color value of the first light-transmitting resin layer 31 and the color value of the light-transmitting substrate 11 may be the same or very similar so as to be nearly the same. The difference in color value between the first light-transmitting resin layer 31 and the light-transmitting substrate 11 may be less than or equal to a predetermined value. For example, each of the first light-transmitting resin layer 31 and the light-transmitting substrate 11 may have a color close to achromatic.

In addition to the matching described above, the refractive index of the second light-transmitting resin layer 32 and the refractive index of the front layer 12 may also be matched with each other. The refractive index of the second light-transmitting resin layer 32 and the refractive index of the front layer 12 may be the same or very similar so as to be nearly the same. The difference between the refractive index of the second light-transmitting resin layer 32 and the refractive index of the front layer 12 may be less than or equal to a predetermined value. For example, the refractive index of the front layer 12 may be defined as an average refractive index over the entire area of the front layer 12 included in one transparent display module 10. For example, the refractive index of the front layer 12 may be defined as a refractive index in an area close to the gap G, that is, an area close to the side surface 12s of the front layer 12. For example, the refractive index of the second light-transmitting resin layer 32 may be approximately 1.4 to 1.51.

In order to improve the degree to which light is emitted forward, according to an embodiment, the refractive index of the light-transmitting cover 40 may be lower than the refractive index of the second light-transmitting resin layer 32. According to an embodiment, the light transmittance of the light-transmitting cover 40 may be higher than the light transmittance of the second light-transmitting resin layer 32.

According to an embodiment, the filler 30 may include a first color material having a black color and a second color material having a color different from black. For example, the second light-transmitting resin layer 32 may include a first color material having a black color and a second color material having a color different from black, and the color of the second light-transmitting resin layer 32 may vary depending on the composition ratio of the first color material and the second color material.

For example, the first color material in black, included in the filler 30, specifically the second light-transmitting resin layer 32, may have a light transmittance of 0.9 or less. For example, the second color material may have a yellowness index of 1 or more.

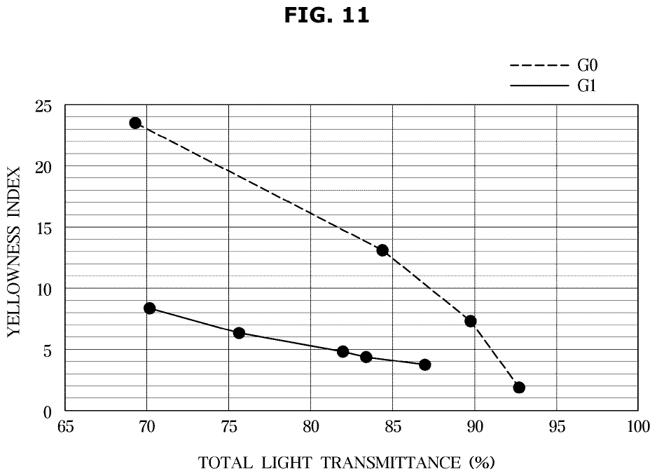

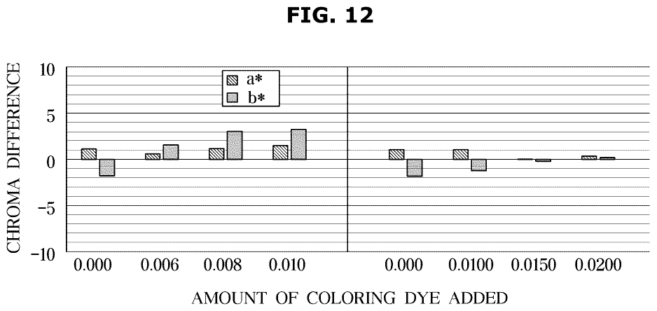

The first color material in black, included in the filler 30, specifically the second light-transmitting resin layer 32, may be a black pigment. For example, the first color material in black may include carbon black. In an embodiment in which black is implemented by carbon black, control of the color of the light-transmitting resin may become easier, and more detailed descriptions thereof will be provided below with reference to FIGS. 11 and 12.

According to an embodiment, the rigidity of the light-transmitting cover 40 may be higher than the rigidity of the first light-transmitting resin layer 31 and the second light-transmitting resin layer 32. Accordingly, the first light-transmitting resin layer 31 and the second light-transmitting resin layer 32 may be protected from external impact. For example, the rigidity may be defined by bending modulus, Young's Modulus, and so on.

In order to prevent and/or reduce the filler 30 from being damaged by external force within the gap G between the plurality of transparent display modules 10, the rigidity (e.g., a bending modulus, Young's modulus of the filler 30 including the first light-transmitting resin layer 31 and the second light-transmitting resin layer 32 may be implemented to be a certain value or less. For example, the bending modulus of the filler 30 including the first light-transmitting resin layer 31 and the second light-transmitting resin layer 32 may be 15,000 MPa or less. For example, the Young's modulus of the filler 30 including the first light-transmitting resin layer 31 and the second light-transmitting resin layer 32 may be 20 MPa or less.

However, the disclosure is not limited thereto, and according to various embodiments, the first light-transmitting resin layer 31 and the second light-transmitting resin layer 32 may have various ranges of rigidity.

According to an embodiment, in order to more effectively prevent/reduce the filler 30 from being damaged, the filler 30 may be configured to have a high adhesion force with the side surface 10s of the transparent display module 10. For example, the first light-transmitting resin layer 31 may have an adhesion force of 1 N/mm² or more with a side surface 11s of the light-transmitting substrate 11. For example, the second light-transmitting resin layer 32 may have an adhesion force of 1 N/mm² or more with a side surface 12s of the front layer 12.

According to an embodiment, the light-transmitting cover 40 may be configured to have a high adhesion force with the front layer 12. For example, the light-transmitting cover 40 may have an adhesion force of 1N/mm² or more with the front surface of the front layer 12.

However, the disclosure is not limited thereto, and in various embodiments, the adhesion force between the first light-transmitting resin layer 31 and the side surface 11s of the light-transmitting substrate 11, the adhesion force between the second light-transmitting resin layer 32 and the side surface 12s of the front layer 12, and the adhesion force between the light-transmitting cover 40 and the front surface of the front layer 12 may be provided in various manners.

According to an embodiment, the plurality of transparent display modules 10 may be attached to the base substrate 20. The transparent display apparatus 1 may include a rear adhesive layer 80 provided to attach the plurality of transparent display modules 10 to the base substrate 20.

The detailed structure of the rear adhesive layer 80 will be described in greater detail below.

According to an embodiment, the transparent display apparatus 1 may include a rear optical layer 60 disposed on the rear surface of the base substrate 20. The rear optical layer 60 may be attached to the rear surface of the base substrate 20. The rear optical layer 60 may be configured to improve the optical performance of the transparent display apparatus 1. For example, the rear optical layer 60 may include an anti-reflection film configured to prevent/reduce thin-film interference caused by light incident on the rear optical layer 60.

According to an embodiment, the transparent display apparatus 1 may include a front optical layer 50 disposed on the front surface of the light-transmitting cover 40. The front optical layer 50 may be attached to the front surface of the light-transmitting cover 40. The front optical layer 50 may be configured to improve the optical performance of the transparent display apparatus 1. For example, the front optical layer 50 may include an anti-reflection film configured to prevent/reduce thin-film interference caused by light incident on the front optical layer 50.

According to an embodiment, the transparent display apparatus 1 may include a front adhesive layer 70 provided to attach the front optical layer 50 to the light-transmitting cover 40.

The detailed structure of the front adhesive layer 70 will be described in greater detail below.

According to an embodiment, the transparent display apparatus 1 may include a protective film 90 disposed on the front surface of the front optical layer 50. The protective film 90 may be attached to the front surface of the front optical layer 50. The protective film 90 may be provided to protect the front surface of the front optical layer 50 from the outside.

The configuration of the transparent display apparatus 1 described with reference to FIG. 6 above is simply an example, and components included in the transparent display apparatus 1 according to various embodiments are not limited thereto, and the transparent display apparatus 1 may include various other configurations.

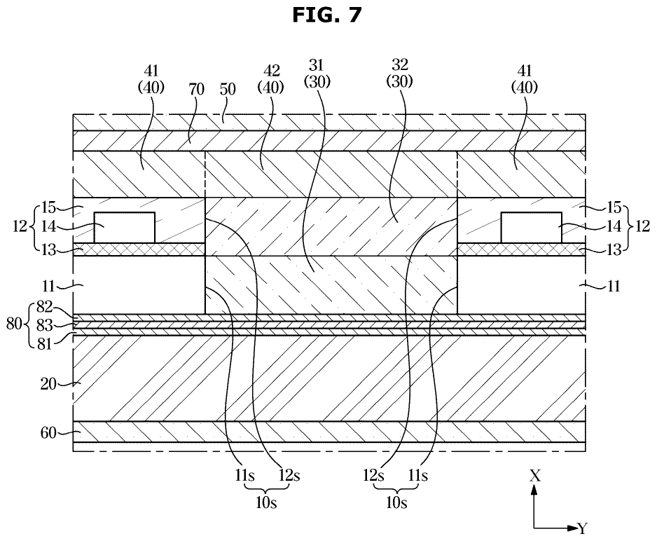

FIG. 7 is an enlarged cross-sectional view illustrating various components of the transparent display apparatus, including a base substrate, a plurality of transparent display modules disposed on the base substrate, a filler disposed in a gap between the plurality of transparent display modules, a light-transmitting cover covering front surfaces of the plurality of transparent display modules and the filler, and a rear adhesive layer for bonding the plurality of transparent display modules to the base substrate according to various embodiments.

Referring to FIG. 7, the rear adhesive layer 80 of the transparent display apparatus 1 according to an embodiment of the present disclosure may include a first rear adhesive 81 provided to be attached to the base substrate 20 and a second rear adhesive 82 provided to be attached to the plurality of display modules 10.

The first rear adhesive 81 may be provided on one surface of the rear adhesive layer 80 facing the base substrate 20. The first rear adhesive 81 may be attached to the front surface of the base substrate 20.

The second rear adhesive 82 may be provided on one surface of the rear adhesive layer 80 facing the plurality of transparent display modules 10. The second rear adhesive 82 may be attached to the rear surfaces of the plurality of display modules 10. The second rear adhesive 82 may be disposed in front of the first rear adhesive 81.

According to an embodiment, the adhesive strength of the first rear adhesive 81 may be greater than the adhesive strength of the second rear adhesive 82.

For example, the first rear adhesive 81 may include an acrylic material. For example, the thickness of the first rear adhesive 81 may be approximately 20 to 100 micrometers. For example, the adhesive strength of the first rear adhesive 81 may be approximately 1N/25 mm or more.

For example, the second rear adhesive 82 may include a silicone material. For example, the thickness of the second rear adhesive 82 may be approximately 20 to 100 micrometers. For example, the adhesive strength of the second rear adhesive 82 may be approximately 0.11N/25 mm or less.

According to such an embodiment, the transparent display module 10 may be easily separated from the base substrate 20 when needed. For example, when a force is applied to the transparent display module 10 at 90 degrees (e.g., when a force is applied to the transparent display module 10 in the X direction with respect to the base substrate 20), the transparent display module 10 may be easily separated from the base substrate 20.

The rear adhesive layer 80 may include a rear adhesive layer base 83 that forms a substrate of the rear adhesive layer 80. The first rear adhesive 81 may be provided on one surface (e.g., a rear surface) of the rear adhesive layer base 83, and the second rear adhesive 82 may be provided on the other surface (e.g., a front surface) of the rear adhesive layer base 83.

For example, the rear adhesive layer base 83 may include a polyethylene terephthalate (PET) material.

However, the disclosure is not limited thereto, and for example, the rear adhesive layer 80 may include a first rear adhesive 81 and a second rear adhesive 82 having substantially the same material and substantially the same adhesive strength. For example, the rear adhesive layer 80 may be formed of the material as a whole.

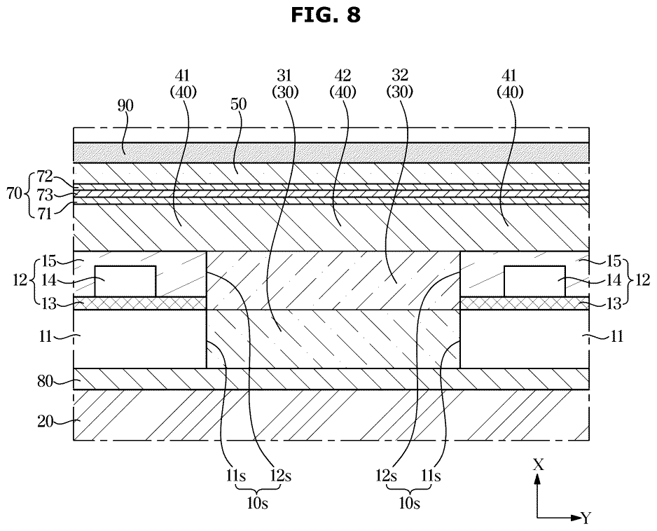

FIG. 8 is an enlarged cross-sectional view illustrating various components of the transparent display apparatus, including a plurality of transparent display modules, a filler disposed in a gap between the plurality of transparent display modules, a light-transmitting cover covering front surfaces of the plurality of transparent display modules and the filler, a front optical layer disposed on a front surface of the light-transmitting cover, a protective film, and a front adhesive layer for bonding the front optical layer to the plurality of transparent display modules according to various embodiments.

Referring to FIG. 8, the front adhesive layer 70 of the transparent display apparatus 1 according to an embodiment of the present disclosure may include a first front adhesive 71 provided to be attached to the light-transmitting cover 40 and a second front adhesive 72 provided to be attached to the front optical layer 50.

The first front adhesive 71 may be provided on one surface of the front adhesive layer 70 facing the light-transmitting cover 40. The first front adhesive 71 may be attached to the front surface of the light-transmitting cover 40.

The second front adhesive 72 may be provided on one surface of the front adhesive layer 70 facing the front optical layer 50. The second front adhesive 72 may be attached to the rear surface of the front optical layer 50. The second front adhesive 72 may be disposed in front of the first front adhesive 71.

According to an embodiment, the adhesive strength of the first front adhesive 71 may be less than the adhesive strength of the second front adhesive 72.

For example, the first front adhesive 71 may include a silicone material. For example, the thickness of the first front adhesive 71 may be approximately 20 to 100 micrometers. For example, the adhesive strength of the first front adhesive 71 may be approximately 5N/25 mm or less.

For example, the second front adhesive 72 may include an acrylic material. For example, the thickness of the second front adhesive 72 may be approximately 20 to 100 micrometers. For example, the adhesive strength of the second front adhesive 72 may be approximately 20N/25 mm or more.

According to an embodiment, the protective film 90 and the front optical layer 50 may be easily separated from the light-transmitting cover 40 when needed. For example, when a 180-degree force is applied to the protective film 90 and the front optical layer 50 (e.g., when a force is applied to the protective film 90 and the front optical layer 50 relative to the light-transmitting cover 40 to separate the protective film 90 and the front optical layer 50 by flipping the protective film 90 and the front optical layer 50 180 degrees in the Y or Z direction), the protective film 90 and the front optical layer 50 may be easily separated from the light-transmitting cover 40.

The front adhesive layer 70 may include a front adhesive layer base 73 that forms a substrate of the front adhesive layer 70. The first front adhesive 71 may be provided on one surface (e.g., a rear surface) of the front adhesive layer base 73, and the second front adhesive 72 may be provided on the other surface (e.g., a front surface) of the front adhesive layer base 73.

For example, the front adhesive layer base 73 may include PET material.

However, the disclosure is not limited thereto, and for example, the front adhesive layer 70 may include a first front adhesive 71 and a second front adhesive 72 having substantially the same material and substantially the same adhesive strength. For example, the front adhesive layer 70 may be formed of the same material as a whole.

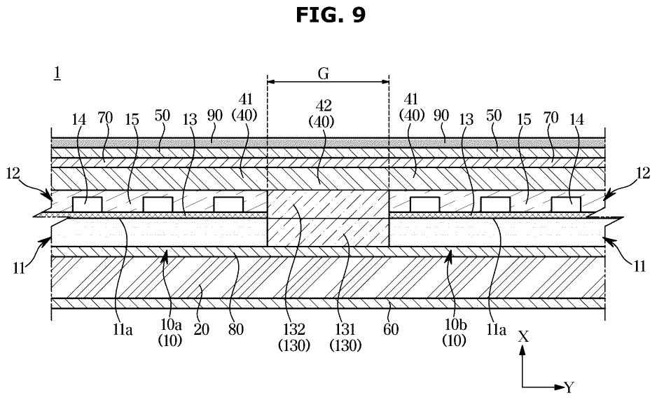

FIG. 9 is an enlarged cross-sectional view illustrating a part of transparent display apparatus according to various embodiments.

In describing an embodiment of the present disclosure with reference to FIG. 9, the same reference numerals are assigned to the same configurations as those in the example described above with reference to FIGS. 1 to 8, and detailed description thereof may not be repeated here.

Referring to FIG. 9, the transparent display apparatus 1 according to an embodiment of the present disclosure may include a filler 130 disposed in the gap G between the plurality of transparent display modules 10.

The filler 130 may include a first light-transmitting resin layer 131 disposed parallel to the light-transmitting substrate 11 and a second light-transmitting resin layer 132 disposed parallel to the front layer 12.

The refractive index of the first light-transmitting resin layer 131 may be matched with the refractive index of the light-transmitting substrate 11. The refractive index of the second light-transmitting resin layer 132 may be the same as the refractive index of the first light-transmitting resin layer 131. For example, the refractive index of the filler 130 may be matched with the refractive index of the light-transmitting substrate 11. For example, the refractive index of the filler 130 in the visible light region may be matched with the refractive index of the light-transmitting substrate 11.

The color value of the second light-transmitting resin layer 132 may be matched with the color value of the front layer 12. The color value of the first light-transmitting resin layer 131 may be the same as the color value of the second light-transmitting resin layer 132. For example, the color value of the filler 130 may be matched with the color value of the front layer 12. For example, the color value according to the yellowness index of the filler 130 may be matched with the color value according to the yellowness index of the front layer 12.

According to an embodiment, the first light-transmitting resin layer 131 and the second light-transmitting resin layer 132 may be formed as one part. The filler 130 may be formed of an integral light-transmitting resin.

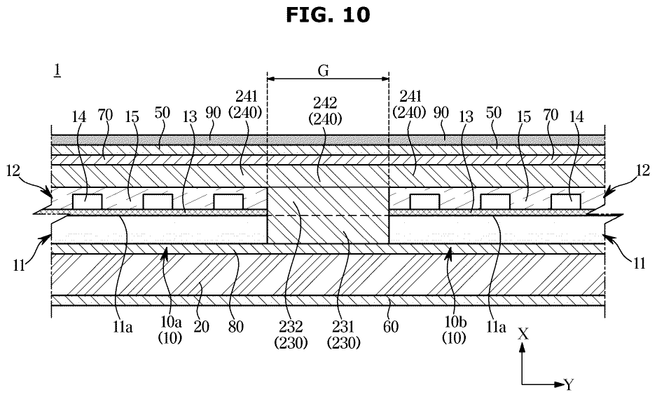

FIG. 10 is an enlarged cross-sectional view illustrating a part of a transparent display apparatus according to various embodiments.

In describing an embodiment of the present disclosure with reference to FIG. 10, the same reference numerals are assigned to the same configurations as those in the example described above with reference to FIGS. 1 to 9, and detailed description thereof may not be repeated here.

Referring to FIG. 10, the transparent display apparatus 1 according to an embodiment of the present disclosure may include a filler 230 disposed in the gap G between the plurality of transparent display modules 10, and a light-transmitting cover 240 disposed in front of the plurality of transparent display modules 10 and the filler 230.

The filler 230 may include a first light-transmitting resin layer 231 disposed parallel to the light-transmitting substrate 11 and a second light-transmitting resin layer 232 disposed parallel to the front layer 12.

The light-transmitting cover 240 may include a first region 241 disposed in front of the plurality of display modules 10 and a second region 242 disposed in front of the second light-transmitting resin layer 232.

According to an embodiment, the refractive index of the first light-transmitting resin layer 231 may be matched with the refractive index of the light-transmitting substrate 11. The refractive index of the second light-transmitting resin layer 232 may be the same as the refractive index of the first light-transmitting resin layer 231. The refractive index of the light-transmitting cover 240 may be the same as the refractive index of the first light-transmitting resin layer 231. For example, the refractive index of the light-transmitting resin including the filler 230 and the light-transmitting cover 240 may be matched with the refractive index of the light-transmitting substrate 11. For example, the refractive index of the filler 230 in the visible light region may be matched with the refractive index of the light-transmitting substrate 11.

The color value of the second light-transmitting resin layer 232 may be matched with the color value of the front layer 12. The color value of the first light-transmitting resin layer 231 may be the same as the color value of the second light-transmitting resin layer 232. The color value of the light-transmitting cover 240 may be the same as the color value of the second light-transmitting resin layer 232. For example, the color value of the light-transmitting resin including the filler 30 and the light-transmitting cover 240 may be matched with the color value of the front layer 12. For example, the color value according to the yellowness index of the light-transmitting resin may be matched with the color value according to the yellowness index of the front layer 12.

According to an embodiment, the first light-transmitting resin layer 231, the second light-transmitting resin layer 232, and the light-transmitting cover 240 may be formed as one part. The light-transmitting resin including the filler 230 and the light-transmitting cover 240 may be formed of an integral light-transmitting resin.

According to an embodiment, the light transmittance of light passing sequentially through the base substrate 20, the light-transmitting substrate 11, the front layer 12, and a first portion of the light-transmitting resin (e.g., the first region 241 of the light-transmitting cover 240) may be matched with the light transmittance of light passing sequentially through the base substrate 20 and a second portion of the light-transmitting resin (e.g., the filler 230 and the second region 242 of the light-transmitting cover 240). For example, the light transmittance may be defined as the transmittance in the visible light region.

FIG. 11 is a graph illustrating a yellowness index according to the total light transmittance in a transparent display apparatus according to various embodiments and a comparative example.

In the graph of FIG. 11, the horizontal axis represents the total light transmittance of the light-transmitting resin, and the total light transmittance may vary depending on the degree to which a coloring component is added to the light-transmitting resin. In the graph of FIG. 11, the vertical axis represents the yellowness index of the light-transmitting resin.

In the graph of FIG. 11, a dotted line G0 relates to a transparent display apparatus according to a comparative example and shows the relationship between the total light transmittance and the yellowness index in an embodiment of a transparent display apparatus in which a general dye is added as a color material included in a light-transmitting resin. A solid line G1 in the graph of FIG. 11 relates to a transparent display apparatus according to an embodiment of the present disclosure and illustrates the relationship between the total light transmittance and the yellowness index in an embodiment of a transparent display apparatus in which a color material including carbon black as a black color material is added to a light-transmitting resin.

Referring to FIG. 11, it can be seen that, compared to the comparative example (G0), embodiments of the present disclosure G1 exhibits less variation in yellowness index with respect to the total light transmittance of the light-transmitting resin. In other words, the color of the light-transmitting resin may be more easily controlled independently of the light transmittance of the light-transmitting resin.

FIG. 12 is a graph illustrating a chroma difference between an area of a transparent display module and a gap area according to the amount of dye added to a light-transmitting resin in a transparent display apparatus according to various embodiments and a comparative example.

In the graph of FIG. 12, the horizontal axis represents the amount of coloring dye added to the light-transmitting resin. In the graph of FIG. 12, the vertical axis represents the chroma difference according to the CIELAB color space between the region of the transparent display module and the region of the gap, specifically the difference in the numerical value a* indicating whether the color is shifted toward red or green and the difference in the numerical value b* indicating whether the color is sifted toward blue or yellow.

The graph on the left side of FIG. 12 relates to a transparent display apparatus according to a comparative example and illustrates the relationship between the chroma difference between the region of the transparent display module and the region of the gap according to the amount of dye added to the light-transmitting resin in an embodiment of a transparent display apparatus in which a general dye is added as a color material included in a light-transmitting resin. The graph on the right side of FIG. 12 relates to a transparent display apparatus according to an embodiment of the present disclosure and shows the relationship between the chroma difference between the region of the transparent display module and the region of the gap according to the amount of dye added to a light-transmitting resin in an embodiment of a transparent display apparatus in which a color material including carbon black as a black color material is added.

Referring to FIG. 12, it can be seen that, compared to the comparative example, embodiments of the present disclosure exhibit a smaller chroma difference between the region of the transparent display module 10 and the region of the gap G, thereby improving he visibility of the gap G.

A transparent display apparatus according to an example embodiment of the disclosure may include: a plurality of transparent display modules arranged in an M×N matrix format; a filler disposed in a gap between the plurality of transparent display modules; and a light-transmitting cover configured to cover front surfaces of the plurality of transparent display modules and a front surface of the filler. Each of the plurality of transparent display modules may include a light-transmitting substrate; and a front layer disposed in front of the light-transmitting substrate, the front layer including a plurality of light-emitting elements mounted on a front surface of the light-transmitting substrate and configured to emit light forward, and a mounting-surface cover surrounding the plurality of light-emitting elements and the front surface of the light-transmitting substrate and configured to allow light to be transmitted therethrough. The filler may include a first light-transmitting resin layer disposed in a gap between light-transmitting substrates of adjacent transparent display modules among the plurality of transparent display modules, arranged parallel to the light-transmitting substrates and having a refractive index matched with a refractive index of the light-transmitting substrates, and a second light-transmitting resin layer disposed in a gap between front layers of the adjacent transparent display modules among the plurality of transparent display modules, arranged parallel to the front layers and having a color value matched with a color value of the front layers.

The light-transmitting cover may include: a first region configured to cover the front surfaces of the plurality of transparent display modules; and a second region configured to cover the front surface of the filler. A transmittance of light sequentially passing through the light-transmitting substrate, the front layer, and the first region may be matched with a transmittance of light sequentially passing through the first light-transmitting resin layer, the second light-transmitting resin layer, and the second region.

A difference between a transmittance of light sequentially passing through the light-transmitting substrate, the front layer, and the first region and a transmittance of light sequentially passing through the first light-transmitting resin layer, the second light-transmitting resin layer, and the second region may be 0.05 or less.

A difference between the refractive index of the light-transmitting substrate and the refractive index of the first light-transmitting resin layer may be 0.03 or less.

A difference between a color value according to yellow index of the front layer and a color value according to yellow index of the second light-transmitting resin layer may be 5 or less.

A refractive index of the second light-transmitting resin layer and a refractive index of the front layer may be matched with each other.

A refractive index of the light-transmitting cover may be smaller than a refractive index of the second light-transmitting resin layer.

The front layer may include a circuit pattern layer provided on the front surface of the light-transmitting substrate and to which the plurality of light-emitting elements may be electrically connected.

The filler may include a first color material having black color and a second color material having a color different from black.

The first color material may include carbon black.

The transparent display apparatus may further include: a base substrate supporting the plurality of transparent display modules and configured to allow light to be transmitted therethrough; and a rear adhesive layer configured to attach the plurality of transparent display modules to the base substrate. The rear adhesive layer may include: a first rear adhesive configured to be attached to the base substrate; and a second rear adhesive configured to be attached to the plurality of transparent display modules. An adhesive strength of the second rear adhesive may be smaller than an adhesive strength of the first rear adhesive.

The transparent display apparatus may further include: a front optical layer covering a front surface of the light-transmitting cover and configured to allow light to be transmitted therethrough; and a front adhesive layer configured to attach the light-transmitting cover to the front optical layer. The front adhesive layer may include: a first front adhesive configured to be attached to the light-transmitting cover; and a second front adhesive configured to be attached to the front optical layer. An adhesive strength of the first front adhesive may be smaller than an adhesive strength of the second front adhesive.

The first light-transmitting resin layer may have a color value that is the same as the color value of the second light-transmitting resin layer, and the second light-transmitting resin layer may have a refractive index that is the same as the refractive index of the first light-Transmitting resin layer.

The light-transmitting cover may have a color value that is the same as the color value of the first light-transmitting resin layer and the color value of the second light-transmitting resin layer. The light-transmitting cover may have a refractive index that is the same as the refractive index of the second light-transmitting resin layer and the refractive index of the first light-transmitting resin layer.

The first light-transmitting resin layer, the second light-transmitting resin layer, and the light-transmitting cover may be formed as one part.

A transparent display apparatus according to an example embodiment of the present disclosure may include: a base substrate configured to allow light to be transmitted therethrough; a plurality of transparent display modules arranged on a front surface of the base substrate; a filler disposed in a gap between the plurality of transparent display modules; and a light-transmitting cover including a first region that covers front surfaces of the plurality of transparent display modules and a second region that covers a front surface of the filler. Each of the plurality of transparent display modules may include: a light-transmitting substrate; a front layer including a circuit pattern layer provided on a front surface of the light-transmitting substrate; a plurality of light-emitting elements mounted on the front surface of the light-transmitting substrate and electrically connected to the circuit pattern layer; and a mounting-surface cover surrounding the circuit pattern layer, the plurality of light-emitting elements, and the front surface of the light-transmitting substrate, and configured to allow light to be transmitted therethrough. The filler may include: a first light-transmitting resin layer disposed parallel to the light-transmitting substrate in the gap and having a refractive index matched with a refractive index of the light-transmitting substrate; and a second light-transmitting resin layer disposed parallel to the front layer in the gap and having a color value matched with a color value of the front layer. The light transmittance of light sequentially passing through the light-transmitting substrate, the front layer, and the first region, and the light transmittance of light sequentially passing through the first light-transmitting resin layer, the second light-transmitting resin layer, and the second region may be matched with each other.

A difference between the light transmittance of light sequentially passing through the light-transmitting substrate, the front layer, and the first region, and the light transmittance of light sequentially passing through the first light-transmitting resin layer, the second light-transmitting resin layer, and the second region may be 0.05 or less.

The rigidity of the light-transmitting cover may be higher than that of the first light-transmitting resin layer and the second light-transmitting resin layer.

The filler may include a first coloring material having a black color and a second coloring material having a color different from black.

A transparent display apparatus according to an example embodiment of the present disclosure may include: a base substrate configured to allow light to be transmitted therethrough; a plurality of transparent display modules mounted on a front surface of the base substrate; and a light-transmitting resin configured to allow light to be transmitted therethrough. Each of the plurality of transparent display modules may include: a light-transmitting substrate; and a front layer disposed on a front surface of the light-transmitting substrate, the front layer including a circuit pattern layer provided on the front surface of the light-transmitting substrate, a plurality of light-emitting elements mounted on the front surface of the light-transmitting substrate and electrically connected to the circuit pattern layer, and a mounting-surface cover that surrounds the circuit pattern layer, the plurality of light-emitting elements, and the front surface of the light-transmitting substrate, and is configured to allow light to be transmitted therethrough. A first portion of the light-transmitting resin may fill the gap between the plurality of transparent display modules. A second portion of the light-transmitting resin may cover front surfaces of the plurality of transparent display modules. The refractive index of the light-transmitting resin may be matched with that of the light-transmitting substrate. The color value of the light-transmitting resin may be matched with that of the front layer. The light transmittance of light sequentially passing through the base substrate, the light-transmitting substrate, the front layer, and the second portion of the light-transmitting resin, and the light transmittance of light sequentially passing through the base substrate and the first portion of the light-transmitting resin may be matched with each other.

According to the present disclosure, the refractive index of a light-transmitting resin disposed in a gap between a plurality of transparent display modules may be matched with that of a light-transmitting substrate of the transparent display modules, thereby reducing the visibility of the gap.

According to the present disclosure, the color value of a light-transmitting resin disposed in a gap between a plurality of transparent display modules may be matched with that of a front layer of the transparent display modules, thereby reducing the visibility of the gap.

According to the present disclosure, the light transmittance of a region corresponding to a gap between transparent display modules may be matched with the light transmittance of a region corresponding to the transparent display modules, thereby reducing the visibility of the gap.

According to the present disclosure, the rigidity of a light-transmitting resin may be appropriately set to prevent and/or reduce the light-transmitting resin disposed in the gap from being damaged.

According to the present disclosure, a rear adhesive layer may include a layer bonded to a transparent display module, the adhesive strength of which is low, thereby allowing the transparent display module to be easily separated from a base substrate when needed.

According to the present disclosure, a front adhesive layer may include a layer bonded to a light-transmitting cover, the adhesive strength of which is low, thereby allowing a front optical layer to be easily separated from the light-transmitting cover when needed.

The effects of the disclosure are not limited to the effects described above, and other effects that are not described will be clearly understood by those skilled in the art from the detailed description.

While the disclosure has been illustrated and described with reference to various example embodiments, it will be understood that the various example embodiments are intended to be illustrative, not limiting. It will be further understood by those skilled in the art that various modifications, alternatives and/or variations of the various example embodiments may be made without departing from the true technical spirit and full technical scope of the disclosure, including the appended claims and their equivalents. It will also be understood that any of the embodiment(s) described herein may be used in conjunction with any other embodiment(s) described herein.

What is claimed is:

1. A transparent display apparatus comprising:
a plurality of transparent display modules, each including a display, arranged in an M×N matrix format;
a filler disposed in a gap between the plurality of transparent display modules; and
a light-transmitting cover configured to cover front surfaces of the plurality of transparent display modules and a front surface of the filler;
wherein each of the plurality of transparent display modules includes:
a light-transmitting substrate; and
a front layer disposed in front of the light-transmitting substrate, the front layer including a plurality of light-emitting elements comprising light-emitting circuitry mounted on a front surface of the light-transmitting substrate and configured to emit light forward, and a mounting-surface cover surrounding the plurality of light-emitting elements and the front surface of the light-transmitting substrate and configured to allow light to be transmitted therethrough;
wherein the filler includes:
a first light-transmitting resin layer disposed in a gap between light-transmitting substrates of adjacent transparent display modules among the plurality of transparent display modules, arranged parallel to the light-transmitting substrates, and having a refractive index matching a refractive index of the light-transmitting substrates; and
a second light-transmitting resin layer disposed in a gap between front layers of the adjacent transparent display modules among the plurality of transparent display modules, arranged parallel to the front layers, and having a color value matching a color value of the front layers.

2. The transparent display apparatus of claim 1, wherein the light-transmitting cover includes:
a first region configured to cover the front surfaces of the plurality of transparent display modules; and
a second region configured to cover the front surface of the filler,
wherein a transmittance of light sequentially passing through the light-transmitting substrate, the front layer, and the first region is matched with a transmittance of light sequentially passing through the first light-transmitting resin layer, the second light-transmitting resin layer, and the second region.

3. The transparent display apparatus of claim 2, wherein a difference between the transmittance of light sequentially passing through the light-transmitting substrate, the front layer, and the first region and the transmittance of light sequentially passing through the first light-transmitting resin layer, the second light-transmitting resin layer, and the second region is 0.05 or less.

4. The transparent display apparatus of claim 1, wherein a difference between the refractive index of the light-transmitting substrate and the refractive index of the first light-transmitting resin layer is 0.03 or less.

5. The transparent display apparatus of claim 1, wherein a difference between a color value according to a yellow index of the front layer and a color value according to a yellow index of the second light-transmitting resin layer is 5 or less.

6. The transparent display apparatus of claim 1, wherein a refractive index of the second light-transmitting resin layer and a refractive index of the front layer match each other.

7. The transparent display apparatus of claim 1, wherein a refractive index of the light-transmitting cover is less than a refractive index of the second light-transmitting resin layer.

8. The transparent display apparatus of claim 1, wherein the front layer includes a circuit pattern layer provided on the front surface of the light-transmitting substrate and to which the plurality of light-emitting elements are electrically connected.

9. The transparent display apparatus of claim 1, wherein the filler includes a first color material having black color and a second color material having a color different from black.

10. The transparent display apparatus of claim 9, wherein the first color material includes carbon black.

11. The transparent display apparatus of claim 1, further comprising:
a base substrate supporting the plurality of transparent display modules and configured to allow light to be transmitted therethrough; and
a rear adhesive layer configured to attach the plurality of transparent display modules to the base substrate;
wherein the rear adhesive layer includes:
a first rear adhesive configured to be attached to the base substrate; and
a second rear adhesive configured to be attached to the plurality of transparent display modules,
wherein an adhesive strength of the second rear adhesive is less than an adhesive strength of the first rear adhesive.

12. The transparent display apparatus of claim 1, further comprising:
a front optical layer covering a front surface of the light-transmitting cover and configured to allow light to be transmitted therethrough; and
a front adhesive layer configured to attach the light-transmitting cover to the front optical layer,
wherein the front adhesive layer includes:
a first front adhesive configured to be attached to the light-transmitting cover; and
a second front adhesive configured to be attached to the front optical layer,
wherein an adhesive strength of the first front adhesive is less than an adhesive strength of the second front adhesive.

13. The transparent display apparatus of claim 1, wherein the first light-transmitting resin layer has a color value that is the same as the color value of the second light-transmitting resin layer, and
the second light-transmitting resin layer has a refractive index that is the same as the refractive index of the first light-transmitting resin layer.

14. The transparent display apparatus of claim 13, wherein the light-transmitting cover has a color value that is the same as the color value of the first light-transmitting resin layer and the color value of the second light-transmitting resin layer, and
the light-transmitting cover has a refractive index that is the same as the refractive index of the second light-transmitting resin layer and the refractive index of the first light-transmitting resin layer.

15. The transparent display apparatus of claim 1, wherein the first light-transmitting resin layer, the second light-transmitting resin layer, and the light-transmitting cover are formed as one part.

16. A transparent display apparatus comprising:
a base substrate configured to allow light to be transmitted through the base substrate;
a plurality of transparent display modules, each including a transparent display, arranged on a front surface of the base substrate;
a filler disposed in a gap between the plurality of transparent display modules; and
a light-transmitting cover including a first region configured to cover front surfaces of the plurality of transparent display modules and a second region configured to cover a front surface of the filler,
wherein each of the plurality of transparent display modules includes:
a light-transmitting substrate; and
a front layer including:
a circuit pattern layer on a front surface of the light-transmitting substrate;
a plurality of light-emitting elements comprising light-emitting circuitry mounted on the front surface of the light-transmitting substrate and electrically connected to the circuit pattern layer; and
a mounting-surface cover surrounding the circuit pattern layer, the plurality of light-emitting elements, and the front surface of the light-transmitting substrate, and configured to allow light to be transmitted through the mounting-surface cover,
wherein the filler includes:
a first light-transmitting resin layer disposed parallel to the light-transmitting substrate in the gap and having a refractive index matching a refractive index of the light-transmitting substrate; and
a second light-transmitting resin layer disposed parallel to the front layer in the gap and having a color value matching with a color value of the front layer, and
wherein a light transmittance of light sequentially passing through the light-transmitting substrate, the front layer, and the first region, and a light transmittance of light sequentially passing through the first light-transmitting resin layer, the second light-transmitting resin layer, and the second region match each other.

17. The transparent display apparatus of claim 16, wherein a difference between the light transmittance of light sequentially passing through the light-transmitting substrate, the front layer, and the first region, and the light transmittance of light sequentially passing through the first light-transmitting resin layer, the second light-transmitting resin layer, and the second region is 0.05 or less.

18. The transparent display apparatus of claim 16, wherein a rigidity of the light-transmitting cover is higher than a rigidity of the first light-transmitting resin layer and a rigidity of the second light-transmitting resin layer.

19. The transparent display apparatus of claim 16, wherein the filler includes a first coloring material having a black color and a second coloring material having a color different from black.

20. A transparent display apparatus comprising:
a base substrate configured to allow light to be transmitted through the base substrate;
a plurality of transparent display modules, each comprising a transparent display, mounted on a front surface of the base substrate; and
a light-transmitting resin configured to allow light to be transmitted through the light-transmitting resin,
wherein each of the plurality of transparent display modules includes:
a light-transmitting substrate; and
a front layer on a front surface of the light-transmitting substrate, the front layer including:
a circuit pattern layer on the front surface of the light-transmitting substrate;
a plurality of light-emitting elements comprising light-emitting circuitry mounted on the front surface of the light-transmitting substrate and electrically connected to the circuit pattern layer; and
a mounting-surface cover surrounding the circuit pattern layer, the plurality of light-emitting elements, and the front surface of the light-transmitting substrate, and configured to allow light to be transmitted through the mounting-surface cover,
wherein a first portion of the light-transmitting resin fills a gap between the plurality of transparent display modules,
wherein a second portion of the light-transmitting resin covers front surfaces of the plurality of transparent display modules,
wherein a refractive index of the light-transmitting resin match a refractive index of the light-transmitting substrate,
wherein a color value of the light-transmitting resin match a color value of the front layer, and
wherein a light transmittance of light sequentially passing through the base substrate, the light-transmitting substrate, the front layer, and the second portion of the light-transmitting resin, and a light transmittance of light sequentially passing through the base substrate and the first portion of the light-transmitting resin match each other.
